(19) United States
(12) Patent Application Publication
(10) Pub. No.: US 2024/0355719 A1
(43) Pub. Date: Oct. 24, 2024

(54) THIN SEMICONDUCTOR DEVICE AND METHOD OF MANUFACTURING THIN SEMICONDUCTOR DEVICE

(71) Applicant: SHUNSIN TECHNOLOGY (ZHONG SHAN) LIMITED, Zhongshan (CN)

(72) Inventor: Shun-Hsing LIAO, Zhongshan City (CN)

(21) Appl. No.: 18/530,645

(22) Filed: Dec. 6, 2023

(30) Foreign Application Priority Data
Apr. 20, 2023 (CN) 202310426168.8

(51) Int. Cl. H01L 23/498; H01L 23/00; H01L 23/66; H05K 3/34

(52) U.S. Cl. CPC H01L 23/49816; H01L 23/66; H01L 24/32; H01L 24/48; H01L 24/73; H05K 3/341; H01L 2223/6677; H01L 2224/32225; H01L 2224/48245; H01L 2224/73265; H01L 2924/15311

(57) ABSTRACT

A thin semiconductor device and a method of manufacturing the thin semiconductor device, comprising a substrate with a first surface, a second surface opposite to the first surface, and a circuit layer. An electronic device is disposed on the first surface and is coupled to the circuit layer. A wire is disposed on the first surface and is coupled to the circuit layer. A molding layer covers the substrate and covers part of the electronic device and the wire. A plurality of antenna units is disposed on the molding layer and is coupled to wire. A plurality of connecting units is disposed on the second surface and is coupled to wire.

### FIELD

The subject matter herein generally relates to a semiconductor device, in particular to a thin semiconductor device and method of manufacturing thin semiconductor device.

### BACKGROUND

Referring to FIG. 1 for the semiconductor structure of a conventional antenna, a semiconductor device 50 of a conventional antenna includes a first wiring board 52, an antenna unit 54, a chip 56 and a second wiring board 58. The upper surface of the first wiring board 52 is provided with a plurality of antenna units 54, and the plurality of antenna units 54 is combined to form an antenna structure. The plurality of antenna units 54 is coupled to the circuit 520 in the first wiring board 52. The chip 56 is disposed on the lower surface of the first wiring board 52 and is coupled to the circuit 520 in the first wiring board 52. The chip 56 can be a radio frequency transceiver (RF transceiver).

In order to protect the chip 56 on the lower surface of the first wiring board 52, a second wiring board 58 is disposed under the first wiring board 52. The way to dispose the second wiring board 58 is to dispose the plurality of connecting units 59 on the lower surface of the first wiring board 52. The plurality of connecting units 59 can be plurality of solder balls. The first wiring board 52 and the second wiring board 58 are connected through the plurality of connecting units 59 to complete the semiconductor device 50. The semiconductor device 50 can be mounted on another circuit board by soldering or other methods to connect other devices such as controllers.

The semiconductor device 50 of the traditional antenna needs to be provided with two wiring boards (the first wiring board 52 and the second wiring board 58) for stacking, the thickness of the semiconductor device 50 cannot be effectively reduced, and the production program is also complicated.

If a semiconductor device with simple and fast manufacturing process, simple structure and thinner structure can be designed, the above problems can be effectively improved.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a cross-sectional view illustrating a conventional semiconductor device.

FIG. 2 is a cross-sectional view illustrating a thin semiconductor device according to an embodiment of the disclosure.

FIG. 3 to FIG. 9 are cross-sectional diagrams illustrating a process flow of a method of manufacturing thin semiconductor device according to an embodiment of the disclosure.

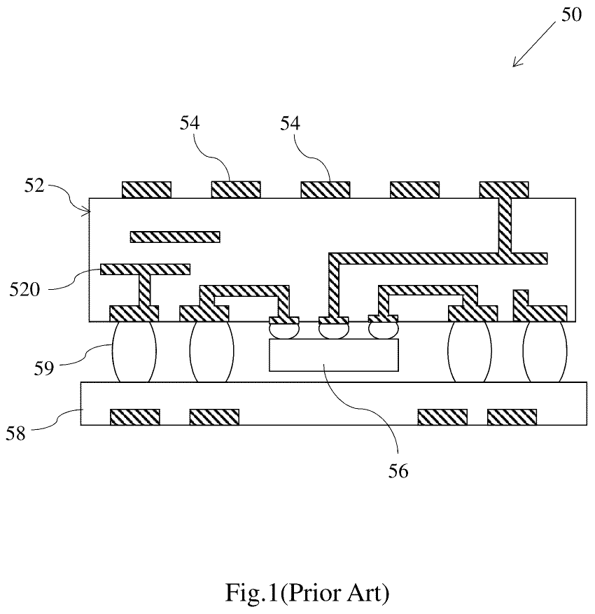

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one”.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to;” it specifically indicates open-ended inclusion or membership in the so-described combination, group, series, and the like.

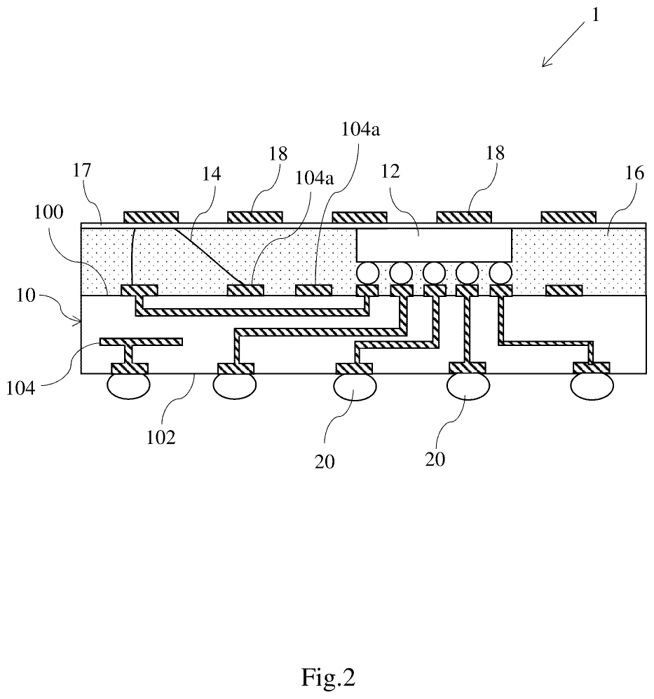

First, the structure of the thin semiconductor device of the embodiment is described. As shown in FIG. 2, the embodiment provides a thin semiconductor device 1, including a substrate 10, at least one electronic device 12, at least one wire 14, and a molding layer 16, a plurality of antenna units 18 and a plurality of connecting units 20. The substrate 10 comprising a first surface 100, a second surface 102 and a circuit layer 104, wherein the second surface 102 is disposed opposite to the first surface 100. The circuit layer 104 further exposes a plurality of conductive contacts 104a on the first surface 100 to electrically connect the electronic device 12 and the plurality of antenna units 18 disposed on the first surface 100. The conductive contact 104a can be a metal conductive sheet, and the electronic device 12 is disposed on the first surface 100 of the substrate 10 and is coupled to the circuit layer 104. The wire 14 is disposed on the first surface 100 of the substrate 10 and is coupled to the circuit layer 104. The molding layer 16 covers the first surface 100 of the substrate 10 and covers part of the electronic device 12 and the wires 14. In this embodiment, the tops of the electronic device 12 and the wires 14 are exposed on the outer surface of the molding layer 16. The plurality of antenna units 18 is disposed on the molding layer 16 and coupled to the wires 14, so that the plurality of antenna units 18 is coupled to the circuit layer 104 and coupled the electronic device 12 through the circuit layer 104. The plurality of connecting units 20 is disposed on the second surface 102 of the substrate 10 and coupled to the circuit layer 104. The plurality of connecting units 20 may be the plurality of solder balls, such as the plurality of tin balls.

In this embodiment, the thin semiconductor device 1 can be a patch antenna device. The electronic device 12 may be a radio frequency transceiver (RF transceiver). The antenna unit 18 can be a conductive pattern, and a plurality of conductive patterns is disposed on the sealing layer 16 to form an antenna.

In this embodiment, the substrate 10 may be a wiring board, and the formation of the substrate 10 may involve multiple deposition or coating processes, patterning processes, and planarization processes. The deposition or coating processes can be used to form insulating layers or the circuit layers 104. The deposition or coating processes may comprise a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the insulating layers and circuit layers 104. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the insulating layers and circuit layers 104 to facilitate subsequent processes. The planarization process may comprise a mechanical polishing process, a chemical mechanical polishing (CMP) process, or other applicable processes and combinations thereof.

The substrate 10 can also be formed by an additive buildup process. The additive buildup process may comprise the alternating stacking of one or more dielectric layers and corresponding conductive patterns or traces of the circuit layers 104. The conductive patterns or traces allow electrical traces out of the occupied space of the electronic device, or are in a fan-shaped layout allowing the electrical traces into the occupied space of the electronic device 12. The conductive patterns can be formed by a plating process such as an electroplating process or an electroless plating process. The conductive pattern may comprise a conductive material, such as copper or other plateable metals. The dielectric layer of the substrate 10 can be made of a photo-definable organic dielectric such as polyimide (PI), benzocyclobutene (BCB), or polybenzoxazole (PBO). In other embodiments, the dielectric material of the substrate 10 may also be an inorganic dielectric layer. The inorganic dielectric layer may comprise silicon nitride (Si₃N₄), silicon oxide (SiO₂), or SiON. The inorganic dielectric layer can be formed by growing an inorganic dielectric layer using an oxidation or nitridation process.

According to the embodiment of the disclosure, the substrate 10 may further comprise a carrier, for example, a printed circuit board (PCB) or a laminated substrate. The carrier can be formed by laminating and build-up methods, which are wholly conventional and will be fully appreciated by those of ordinary skill in the art. The material of the dielectric structure inside the carrier may comprise epoxy resin, phenolic resin, glass epoxy resin, polyimide, polyester, epoxy molding compound, or ceramic. The material of the wires inside the carrier may comprise copper, iron, nickel, gold, silver, palladium, or tin.

In FIG. 2 of this embodiment, only a single electronic device 12 is shown, however, the actual number is not limited thereto, and those skilled in the art can set a specific number of electronic devices 12 according to actual needs. The electronic device 12 may be a semiconductor die, a semiconductor wafer, or a package including a plurality of electronic devices.

In this embodiment, when the electronic device 12 is disposed on the first surface 100, the electronic device 12 can be coupled to the circuit layer 104 of the substrate 10. Before installing the electronic device 12, a soldering layer can be disposed on the first surface 100 to assist in installing the electronic device 12 on the first surface 100. In this embodiment, the soldering layer may be Flux, and in one embodiment, the flux may be one of three types of fluxes: inorganic flux, organic flux, or rosin flux. Inorganic flux can be added with hydrochloric acid, hydrofluoric acid, zinc chloride or ammonium chloride and other inorganic acids and inorganic salt flux. The organic flux can be a weakly acidic organic acid flux such as lactic acid or citric acid. Rosin-based fluxes are fluxes with rosin added. In addition, the electronic device 12 can be coupled to the circuit layer 104 of the substrate 10 via conductive wires such as gold wires, copper wires or aluminum wires.

In this embodiment, the wire 14 can be a conductive wire such as gold wire, copper wire or aluminum wire, so as to connect to the circuit layer 104 of the substrate 10. In this embodiment, the wire 14 can be coupled to the circuit layer 104 of the substrate 10 through wire bonding.

In this embodiment, the molding layer 16 can be Epoxy Molding Compound, (EMC). In other embodiment, the material of the molding layer 16 can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

The plurality of antenna units 18 can be fixed on the sealing layer 16 through an adhesive layer 17. In this embodiment, the adhesive layer 17 can be silver glue, which is laid on the molding layer 16 by screen printing silver glue, so as to provide the effect of fixing the antenna unit 18.

The plurality of connecting units 20 can be implanted on the second surface 102 of the substrate 10 through Ball Implantation, and the thin semiconductor device 1 according to an embodiment of the present application can utilize the plurality of connecting units 20 and external devices (such as printed circuit boards) are electrically connected. In this embodiment, the plurality of connecting units 20 is solder balls, and the material may be the plurality of tin balls.

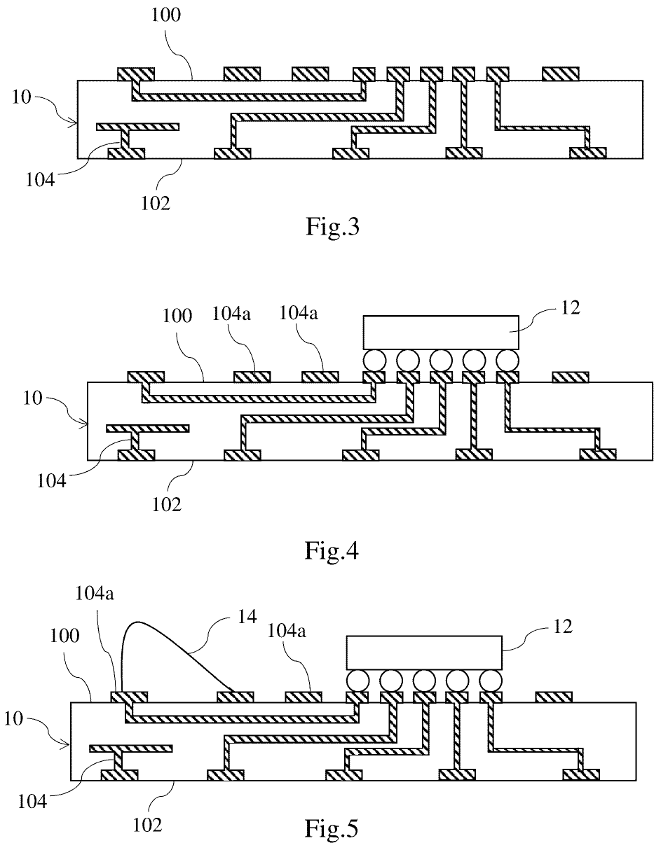

After the structure of the thin semiconductor device 1 has been described above, the method for manufacturing the thin semiconductor device 1 of the embodiment will be described next. Please refer to FIG. 3 to FIG. 9 to illustrate the steps of the manufacturing method of the thin semiconductor device 1. Referring first to FIG. 3, a substrate 10 is provided. The substrate 10 has a first surface 100, a second surface 102 and a circuit layer 104, wherein the second surface 102 is disposed opposite to the first surface 100.

Next, as shown in FIG. 4, the electronic device 12 is disposed on the first surface 100, so that the electronic device 12 is coupled to the circuit layer 104 through the conductive contact 104a. In this embodiment, before the electronic device 12 is installed, a soldering layer will be laid on the first surface 100 of the substrate 10 to remove the surface tension and oxides on the first surface 100, so as to obtain a clean soldering surface and assist the electronic device 12 is soldered on the first surface 100 and electrically connected to the circuit layer 104.

After the step of installing the electronic device 12 on the substrate 10, please refer to FIG. 5, then set the wire 14 on the first surface 100, and the wire 14 is coupled to the circuit layer 104 through the conductive contact 104a. In this embodiment, the wire 14 is coupled to the circuit layer 104 of the substrate 10 by wire bonding. Wire bonding can be in the form of wedge bonding, ball bonding, or reverse bonding.

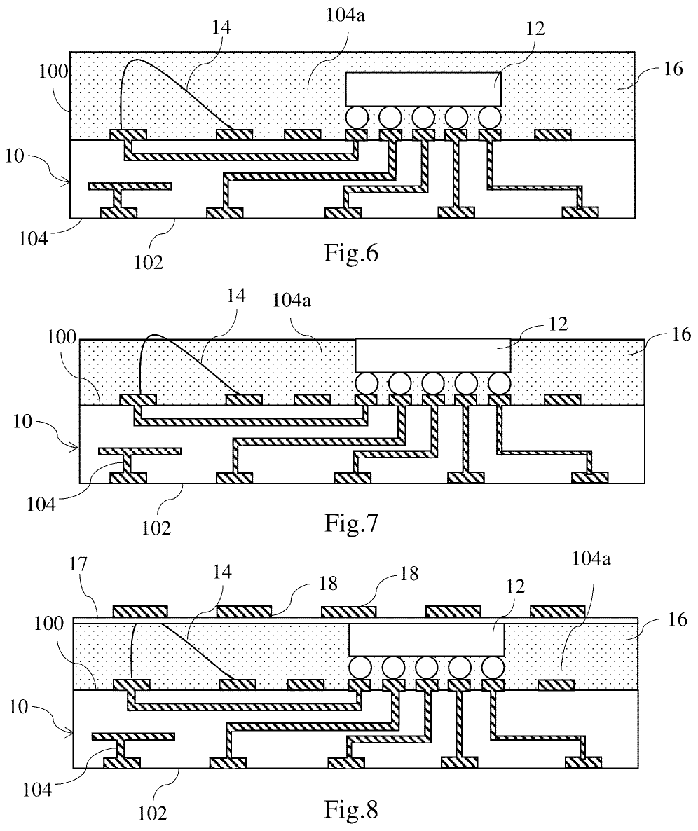

Please refer to FIG. 6 for the next steps, forming a molding layer 16 on the first surface 100, and the molding layer 16 covers the electronic device 12 and the wires 14 to package and protect the electronic device 12 and the wires 14. Since the wires 14 are provided by wire bonding, when the molding layer 16 is formed, the wires 14 can be effectively prevented from being toppled or displaced. Next, please refer to FIG. 7, use a polishing to polish the molding layer 16, so that the electronic device 12 and wires 14 covered by the molding layer 16 can be exposed on the outer surface of the molding layer 16. In this embodiment, the top of the electronic device 12 and parts of the wires 14 are exposed outside the molding layer 16.

Please refer to FIG. 8 for the next step, which is to dispose a plurality of antenna units 18 on the molding layer 16. In this embodiment, before the plurality of antenna units 18 is disposed, the adhesive layer 17 is coated on the sealing layer 16. The adhesive layer 17 can be silver glue, which is laid on the molding layer 16 by screen printing, so as to assist the plurality of antenna units 18 to be disposed on the molding layer 16 to form an antenna.

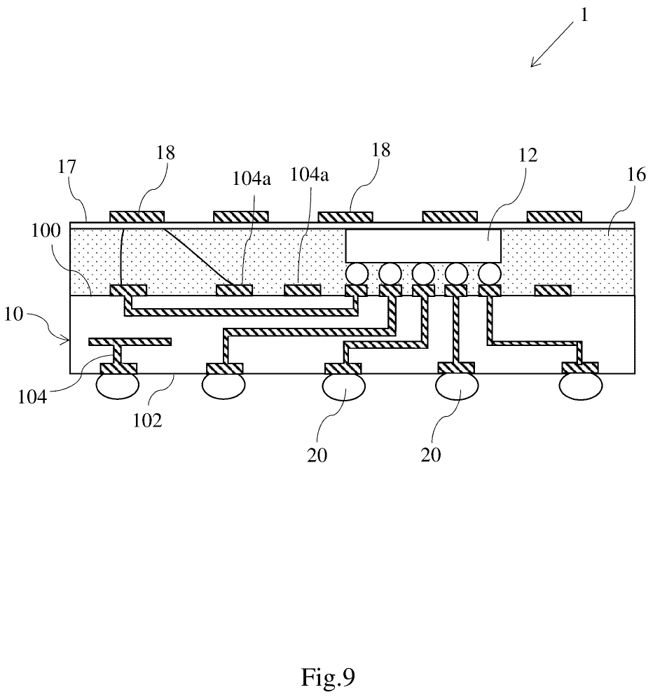

Finally, referring to FIG. 9, a plurality of connecting units 20 is disposed on the second surface 102, and the plurality of connecting units 20 is coupled to the circuit layer 104. The plurality of connecting units 20 can be implanted on the second surface 102 of the substrate 10 through ball implantation, and according to the embodiment, the thin semiconductor device 1 can use the plurality of connecting units 20 to electrically connect with external devices (such as, printed circuit boards).

The thin semiconductor device 1 in this embodiment can be fabricated through the sequential steps disclosed in the above-mentioned FIG. 3 to FIG. 9. By utilizing the thin semiconductor device and method of manufacturing thin semiconductor device of the present invention, the overall thickness of the thin semiconductor device 1 can be significantly reduced, so that the overall thickness of the thin semiconductor device 1 is only 100-300 microns (μm), compared with traditional semiconductor devices, the overall thickness reduced by 150˜500 microns (μm). Encapsulation with the sealant layer 16, in addition to protecting the electronic device 12, can reduce the use of two substrates to assemble a semiconductor device at the same time, effectively saving development costs and shortening the production schedule, and using wire bonding to arrange the wires 14, it also makes the production process simpler and more cost-effective relatively.

Many details are often found in the relevant art and many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A thin semiconductor device comprising:
a substrate comprising a first surface, a second surface opposite to the first surface, and a circuit layer;
an electronic device is disposed on the first surface and is coupled to the circuit layer;
a wire is disposed on the first surface and is coupled to the circuit layer;
a molding layer covers the substrate and covers a part of the electronic device and the wire;
a plurality of antenna units is disposed on the molding layer and is coupled to the wire; and
a plurality of connecting units is disposed on the second surface and is coupled to the circuit layer.

2. The thin semiconductor device of claim 1, wherein the wire is coupled to the circuit layer through wire bonding.

3. The thin semiconductor device of claim 1, wherein an adhesive layer is disposed on a sealing layer, and the plurality of antenna units is fixed on the sealing layer through the adhesive layer.

4. The thin semiconductor device of claim 3, wherein the sealing layer is Epoxy Molding Compound (EMC).

5. The thin semiconductor device of claim 1, wherein the electronic device is a radio frequency transceiver (RF transceiver), and each of the plurality of antenna units is a conductive pattern.

6. The thin semiconductor device of claim 1, wherein the circuit layer includes a plurality of conductive contacts, which is exposed on the first surface.

7. The thin semiconductor device of claim 6, wherein the plurality of conductive contacts is coupled to the electronic device and the plurality of antenna units.

8. The thin semiconductor device of claim 1, wherein the plurality of connecting units is solder balls.

9. A method of manufacturing a thin semiconductor device, the method comprising:
providing a substrate comprising a first surface, a second surface opposite to the first surface, and a circuit layer;
disposing an electronic device on the first surface and coupling the electronic device to the circuit layer;
disposing a wire on the first surface and coupling the wire to the circuit layer;
forming a molding layer on the first surface and covering a part of the electronic device and the wire;
polishing the molding layer to expose a top of the electronic device and a portion of the wire; and
disposing a plurality of antenna units on the molding layer, and coupling the plurality of antenna units to the wire; and
disposing a plurality of connecting units on the second surface and coupling the plurality of connecting units to the circuit layer.

10. The method of claim 9, wherein the wire is coupled to the circuit layer through wire bonding.

11. The method of claim 9, further comprising:
disposing a soldering layer on the first surface before disposing the electronic device on the first surface, which helps fix the electronic device onto the first surface.

12. The method of claim 9, further comprising:
disposing an adhesive layer on a sealing layer before disposing the plurality of antenna units on the molding layer, which helps fix the plurality of antenna units onto the sealing layer.

13. The method of claim 12, wherein the sealing layer is Epoxy Molding Compound (EMC).

14. The method of claim 9, wherein the circuit layer includes a plurality of conductive contacts, which is exposed on the first surface.

15. The method of claim 14, wherein the plurality of conductive contacts is coupled to the electronic device and the plurality of antenna units.
